(19) United States
(12) Patent Application Publication
(10) Pub. No.: US 2006/0170822 A1
(43) Pub. Date: Aug. 3, 2006

(54) Image display device and image display method thereof

(76) Inventors: Masahiro Baba, Kanagawa (JP); Go Ito, Tokyo (JP); Nao Mishima, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/326,521

(22) Filed: Jan. 6, 2006

(30) Foreign Application Priority Data
Jan. 6, 2005 (JP) 2005-1887

(51) Int. Cl. H04N 5/21; H04N 9/455; H04N 9/44; H04N 9/45; H04N 5/04

(52) U.S. Cl. 348/500; 348/631; 348/506

(57) ABSTRACT

An image display device comprising: a display 18 to display an input image and a black image within one frame period; a motion detector 14 to detect a motion information from the input image; a display ratio controller 16 to set a black display time ratio as a ratio of a black period to said one frame period based on the motion information, the black period being a period for displaying the black image within said one frame period; and a display luminance controller 30 to suppress, within a predetermined range, a luminance fluctuation caused by a change in the black display time ratio, the luminance fluctuation corresponding to a fluctuation of a total luminance for said one frame period.

### CROSS-REFERENCE TO RELATED APPLICATIONS

This application is based upon and claims the benefit of priority from the prior Japanese Patent Application No. 2005-1887, filed on Jan. 6, 2005; the entire contents of which are incorporated herein by reference.

### TECHNICAL FIELD

The present invention relates to an image display device capable of enhancing picture quality of a motion picture and a still picture while suppressing an increase in a consumed power.

### BACKGROUND OF THE INVENTION

In recent years, a performance of a thin image display device such as a liquid crystal display device or an organic EL (electroluminescence) display device has been enhanced, and also has started to spread in the television field in which a cathode ray tube (hereinafter referred to as a CRT) is conventionally a mainstream.

However, the liquid crystal display device and the organic EL display device have a problem in that a motion picture is blurred when it is displayed. This problem is generated because a temporal characteristic of an image display method is varied between the liquid crystal display device or the organic EL display device and the CRT. The cause for the problem will be briefly described below.

A liquid crystal display device and an organic EL display device which use a transistor as a selecting switch for a display/non-display for each pixel employs a display method (hereinafter referred to as a hold-type display) for holding a displayed image for one frame period. On the other hand, the CRT is a display device employing a display method in which each pixel is turned on for a constant period and is then darkened (which will be hereinafter referred to as an impulse type display).

In case of the hold type display, a motion picture is maintained to be exactly displayed from the display of each frame of the same image to the display of a next frame. For a duration from the display of a frame N in the motion picture to the display of a next frame (N+1) (during a frame), the same image as that in the frame N is displayed. In the case in which a moving object is projected onto the motion picture, it is stationary from the display of the frame N to the display of the frame (N+1) over a screen. The dynamic body is moved discontinuously when the frame (N+1) is displayed.

On the other hand, in the case in which an observer pays attention to the moving object and follows and observes the moving object (in the case in which the eyeball motion of the observer is a following motion), the observer tries to move eyeballs and to follow the moving object unconsciously, continuously and smoothly.

Consequently, a difference is made between the motion of the moving object over the screen and the motion of the moving object which is supposed by the observer. Due to the difference, there is presented a shifted image corresponding to a speed of the moving object over the retina of the observer. Since the observer is conscious of a shifted image obtained by superposing the shift images, he (she) gets an impression that the motion picture is blurred.

When the motion picture is moved more quickly, the shift of the image which is presented over the retina of the observer is increased. For this reason, the observer gets an impression that the motion picture is more blurred.

In case of the impulse type display, such a “blur” is not generated. In case of the impulse type display, a black image is displayed between the frames of the motion picture (for example, between the frame N and the frame (N+1)).

The black color is displayed between the frames. Also in the case in which the observer moves the eyeballs to smoothly follow the moving object, therefore, the observer can see an image the moment the image is displayed. The observer recognize some frame of the motion pictures as independent images, respectively. For this reason, the images presented on the retina can be prevented from being shifted.

In order to solve the problem in the display device which carries out the hold type display, a technique which displays a “black” by some means after displaying a frame has been proposed in Japanese Application Kokai No. 11-109921.

Moreover, a technique to decide whether an input image is a motion picture or a still picture and to display a black color between continuous frames only in case of the motion picture has been proposed in Japanese Application Kokai No. 2002-123223.

In the Patent Document 1, a screen of a liquid crystal is intentionally set to be “black” between the frames and an impulse type display such as a CRT is thus carried out falsely, resulting in suppression in deterioration in the picture quality of the motion picture. However, the consumed power of a backlight which is also ON for a black display period is wasteful. Moreover, there is a problem in that a flicker is caused by the impulse type display in a still picture.

In the Patent Document 2, a control to carry out the hold type display in the display of a still picture and the impulse type display in the display of a motion picture is performed in order to solve the problem. In the method, however, the black image is displayed between two frames in a motion picture having a small motion and a motion picture having a great motion in the same manner, for example. For this reason, it is impossible to obtain a sufficient power consuming effect. In order to enhance the power consuming effect, for example, the criteria of the motion picture and the still picture can also be set close to the motion picture. In that case, however, the picture quality of the motion picture is deteriorated.

The invention has been made in consideration of the problem and has an object to provide an image display device which enhances the picture quality of dynamic and still pictures displayed on a liquid crystal display device while suppressing an increase in a consumed power, and an image display method thereof.

### BRIEF SUMMARY OF THE INVENTION

According to embodiments of the present invention, an image display device comprises a display to display an input image and a black image for one frame period,

a motion detector to detect a motion of the input image, thereby outputting motion information,

a display ratio controller to set a black display time ratio which displays the black image for one frame period based on the motion information, and

a display luminance controller to suppress, within a predetermined range, a fluctuation in a luminance of the display for one frame period which is caused by a change in the black display time ratio.

According to the invention, it is possible to enhance the picture quality of dynamic and still pictures displayed on the image display device while suppressing an increase in a consumed power.

### BRIEF DESCRIPTION OF THE DRAWINGS

FIG. 1 is a diagram showing a structure of a liquid crystal display device according to a first embodiment of the invention,

FIG. 2 is a typical view showing a method of detecting a motion according to the first embodiment,

FIG. 3 is a diagram showing a relationship between a speed of a moving object and a black display time ratio according to the first embodiment,

FIG. 4 is a diagram showing a structure of a liquid crystal panel according to the first embodiment,

FIG. 5 is a diagram showing an operation of the liquid crystal panel according to the first embodiment,

FIG. 6 is a view showing a state of a display of the liquid crystal display device according to the first embodiment,

FIG. 7 is a chart showing a relationship among a black display time ratio, a relative transmittance of the liquid crystal panel, a relative luminance of a backlight and a relative luminance of the liquid crystal display device according to the first embodiment,

FIG. 8 is a diagram showing a structure of a liquid crystal display device according to a second embodiment,

FIG. 9 is a diagram showing a structure of a liquid crystal display device according to a third embodiment,

FIG. 10 is a table showing a memory capacity according to the third embodiment,

FIG. 11 is a diagram showing a structure of a liquid crystal display device according to a fourth embodiment,

FIG. 12 is a chart showing an operation according to the fourth embodiment,

FIG. 13 is a diagram showing a structure of a liquid crystal display device according to a fifth embodiment,

FIG. 14 is a view showing a structure of a backlight according to the fifth embodiment,

FIG. 15 is a chart showing an operation according to the fifth embodiment,

FIG. 16 is a diagram showing a structure of an organic EL display device according to a sixth embodiment, and

FIG. 17 is a diagram showing the structure of the organic EL panel according to the sixth embodiment.

### DETAILED DESCRIPTION OF THE INVENTION

Embodiments of an image display device according to the invention will be described below with reference to the drawings.

### First Embodiment

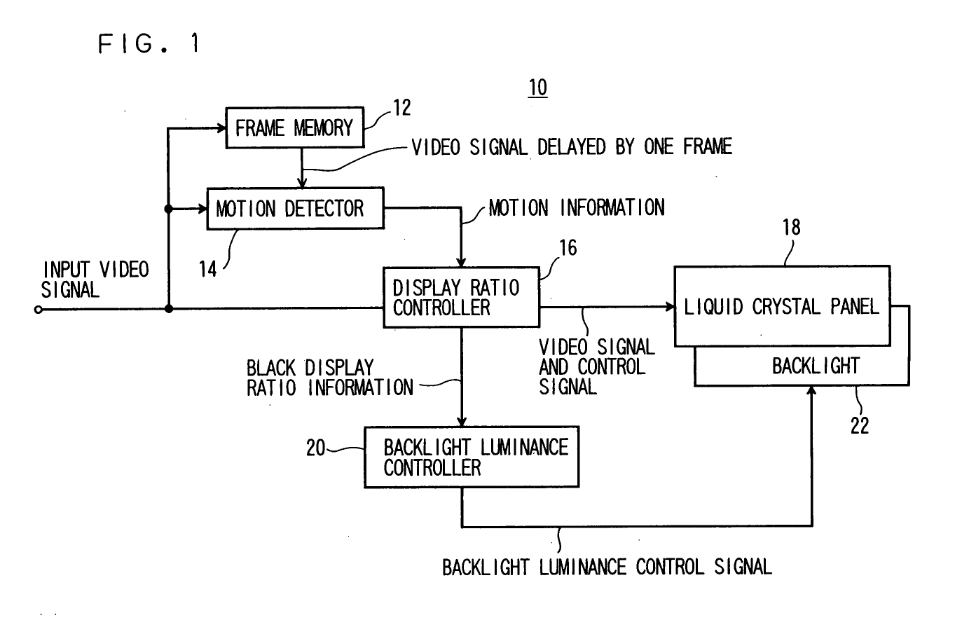

A liquid crystal display device 10 according to a first embodiment of the invention will be described with reference to FIGS. 1 to 7.

(1) Structure of Liquid Crystal Display Device 10

FIG. 1 shows a structure of the liquid crystal display device 10 according to the embodiment.

An input image signal is input to a frame memory 12, a motion detector 14 and a display ratio controller 16.

The frame memory 12 holds an input image signal for one frame period and outputs as an image signal delayed by one frame to the motion detector 14. The “one frame” indicates one image to be displayed on the liquid crystal display device 10 and it is assumed that one field which is generally referred in an interlace image signal and the one frame are indicated to, each other.

The motion detector 14 uses an input image signal and an image signal delayed by one frame period through the frame memory 12, thereby detecting a motion between two temporal adjacent frames and outputting a result as motion information to the display ratio controller 16.

The display ratio controller 16 determines a display ratio for one frame period of a black displayed between frames of the input image signal displayed on a liquid crystal panel 18 based on the input motion information, and outputs the display ratio as black display time ratio information to a backlight luminance controller 20. Moreover, an image signal and a control signal (a horizontal synchronizing signal or a vertical synchronizing signal) are output to the liquid crystal panel 18.

The backlight luminance controller 20 determines a luminance of a backlight 22 based on black display time ratio information which is input, and outputs the luminance as a backlight luminance control signal to the backlight 22.

The liquid crystal panel 18 displays an image signal inserting the black display between the frames based on the image signal and the control signal which are input. Moreover, the backlight 22 emits a light in a luminance based on the backlight luminance control signal.

Next, description will be given to a structure and a function in each portion.

(2) Motion Detector 14

(2-1) Function of Motion Detector 14

The motion detector 14 detects a motion by using a plurality of frames of an input image signal and outputs the motion as motion information. In the embodiment, the input image signal is held for one frame period by the frame memory 12 and the motion is detected by using the image signal delayed by one frame and the input image signal, that is, two frames which are temporal adjacent to each other.

The frame which detects the motion is not restricted to temporal adjacent two frames. In the case in which the input image signal is an interlace image signal, for example, the motion may be detected by using only an even field or an odd field.

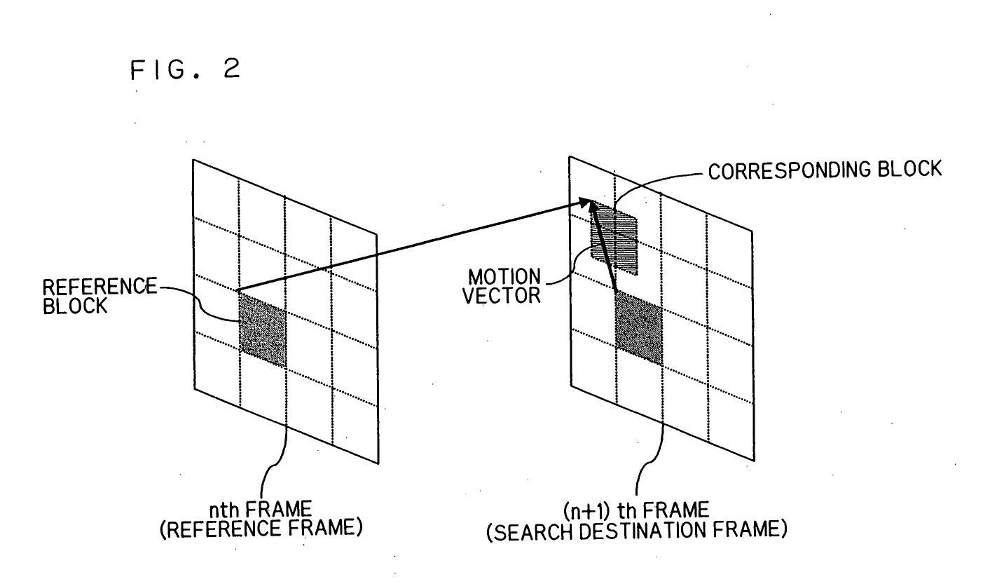

Although various motions detecting means can be proposed, a technique to obtain a motion vector by block matching is employed in the embodiment. The “block matching” is a motion vector detecting technique which is used for coding a motion picture such as Moving Picture Experts Group (MPEG), and divides an nth frame (a reference frame) of an input image signal into square regions (blocks) and searches for an similar region of an (n+1)th frame (a search destination frame) every block as shown in FIG. 2. While a sum of absolute difference (SAD) or a sum of squared difference (SSD) is generally used for a method of evaluating the similar region, the SAD is used to carry out a calculation in accordance with Equation 1 in the embodiment.

$$SAD ( d ) = {\sum }_{x ∈ B} \vert p ( x , n ) - p ( x + d , n + 1 ) \vert \qquad [ Equation 1 ]$$

wherein p(x, n) represents a pixel value in a position x of the nth frame and B represents a region of the reference block. The SADs for various d are obtained by using the Equation 1 and d having minimum SAD is presumed to be the motion vector of the reference block B. This is expressed in Equation 2.

$$MV = arg {min}_{d} SAD ( d ) \qquad [ Equation 2 ]$$

By solving the Equations 1 and 2 for all of the blocks of the reference frame, it is possible to obtain a motion vector between the temporal adjacent frames of the input image signal.

(2-2) Method of Obtaining Motion Information

Next, description will be given to a method of obtaining motion information from a motion vector which is detected.

The liquid crystal display device 10 controls a display ratio of a black display period to one frame period based on the motion information of the input image signal. More specifically, in case of a still picture, the black display to enhance the picture quality of a motion picture is not required but a black display time ratio may be zero. On the other hand, in the case in which the input image includes a motion, it is necessary to determine the black display time ratio corresponding to the motion. More specifically, in the case in which a deterioration in the picture quality caused by a hold effect due to the motion included in the input image is great, the black display time ratio is increased. On the other hand, in the case in which the deterioration in the picture quality caused by the hold effect due to the motion included in the input image is small, the black display time ratio is reduced.

It is possible to variously propose motion information to greatly influence the deterioration in the picture quality caused by the hold effect, that is, motion information to determine the black display time ratio. In the embodiment, the following information 1) to 4) are employed.

1) Speed of motion,

2) Directivity of motion,

3) Contrast of moving object, and

4) Spatial frequency of moving object.

The “Speed of motion” indicates a speed of a moving object included in the input image. The black display time ratio is increased when the speed of the motion is high, and the black display time ratio is reduced when the speed of the motion is low. A still picture is displayed when the speed of a motion is zero. The reason is as follows. A higher speed of the motion increases the amount of a shift which is superposed on the retina by the following operation of the eyes of an observer after the moving object. Accordingly, the deterioration in the picture quality caused by the hold effect is increased.

The “Directivity of motion” indicates how to disperse the direction of the motion included in the input image. The deterioration in the picture quality which is caused by the hold effect is caused when the eyes of the observer follows the moving object. If all of the motions included in the input image are uniform in the same direction, therefore, the deterioration-in the picture quality which is caused by the hold effect becomes remarkable. To the contrary, if the motion included in the input image is carried out in various directions, it is hard for the eyes of the observer to follow the moving object so that the deterioration in the picture quality which is caused by the hold effect is reduced. Accordingly, it is preferable to increase the black display time ratio if the dispersion of the directivity of the motion is smaller, and to reduce the black display time ratio if the dispersion of the directivity of the motion is greater.

The “Contrast of moving object” indicates a difference in a gray-scale level between a still picture background and a moving object. The deterioration in the picture quality which is caused by the hold effect is a blur. When the difference in a gray-scale level between the still picture background and the moving object is reduced, the blur generated on a boundary between the still picture background and the moving object is recognized with more difficulty. As an extreme example, in the case in which the difference in a gray-scale level between the still picture background and the moving object is zero, the blur is not recognized. Accordingly, the black display time ratio is increased when the contrast of the moving object is higher, and the black display time ratio is reduced when the contrast of the moving object is lower.

The “Spatial frequency of moving object” indicates a fineness of a texture of a moving object. Although the deterioration in the picture quality which is caused by the hold effect is recognized as the blur by the observer, the blur is generated on an edge of the moving object. Even if a moving object having a single color is moved, for example, the blur is not recognized because the edge is not present in the moving object. On the other hand, in the case in which a texture (for example, a striped pattern) is present in the moving object, the observer recognizes the blur of the texture in the moving object. Accordingly, it is preferable to increase the black display time ratio when the spatial frequency of the moving object is higher and to reduce the black display time ratio when the spatial frequency of the moving object is lower.

(2-3) Method of Obtaining Information from Input Image

Next, description will be given to a method of obtaining the information as a parameter of motion information from an input image. In the embodiment, a difference between temporal adjacent frames is obtained before the detection of a motion and the calculation of motion information, and a still picture and a motion picture are decided roughly from the difference value between the frames. More specifically, a threshold calculation is carried out for the absolute difference value between the frames. If the absolute difference value is smaller than the threshold, a decision of the still picture is made and the detection of the motion and the calculation of the motion information are not carried out but the motion information is output as the still picture. If the absolute difference value is equal to or greater than the threshold, the detection of the motion and the calculation of the motion information are carried out and the four parameters are output as the motion information.

(2-3-1) Speed of Motion

1) By the method, a motion vector for each frame is estimated and the motion vector having a scalar quantity of 1 or more is obtained.

2) The motion vector is classified into a motion range in eight directions every 45 degrees and the number of the motion vectors corresponding to each motion range is obtained every motion range.

3) The number of the motion vectors for each motion range which is obtained in the 2) is arranged in descending order, and a rate of the number of the motion vectors corresponding to each motion range to the number of the motion vectors having a scalar quantity of 1 or more which is obtained in the 1) is calculated and the motion vector range in which the rate reaches 90% or more in total is acquired.

4) In each motion vector range obtained in the 3), a rate to the number of the motion vectors having the scalar quantity of 1 obtained in the 1) which is lower than 5% is rounded down.

5) Every motion vector range obtained in the 4), a scalar average of the motion vector corresponding to each motion range is obtained and a weight is then averaged in the rate of each motion range obtained in the 3) to calculate a speed of the motion.

(2-3-2) Directivity of Motion

The number of the motion vector ranges obtained in the 1) to 4) for the speed of the motion is set to be a directivity of the motion.

(2-3-3) Contrast of Moving object

1) An absolute difference in a pixel value between the temporal adjacent frames is calculated.

2) A pixel having the absolute difference value of 10 or more is set to be a motion region and a sum of the absolute difference values in the motion region is calculated.

3) A numeric value obtained by dividing the sum of the absolute difference values by the number of the pixels in the motion region having the absolute difference value of 10 or more is set to be a contrast of the moving object.

(2-3-4) Spatial Frequency of Moving object

1) An edge direction of a frame image is detected.

2) A motion vector of the frame image is estimated and the motion vector having a scalar quantity of 1 or more is obtained.

3) An inner product is calculated in the case in which the edge direction obtained in the 1) and the motion vector obtained in the 2) are set to be 1, and a sum thereof is set to be a spatial frequency of the moving object.

The four parameters obtained by the method are output as the motion information to the display ratio controller 16.

(2-4) Variant of Motion Information

The motion information is not restricted to the four parameters but other parameters may be added.

Moreover, a part of the four parameters may be used.

Furthermore, the four parameters are not restricted to the calculating method described above but other methods may be used. For example, the specific value shown in the method may be replaced with other numeric values. It is desirable that the motion information should be determined from a processing quantity and precision.

(3) Display Ratio Controller 16

(3-1) Function of Display Ratio Controller 16

In the display ratio controller 16, a black display time ratio between the display frames for one frame period is calculated based on the input motion information. In the embodiment, the black display time ratio is calculated by Equation 3 by using a linear sum of the four motion information obtained in the motion detector 14.
BDR=a×spd+b×dir+c×cr+d×freq+e [Equation 3]
wherein BDR represents a black display time ratio (%), spd represents a speed of a motion, dir denotes a directivity of the motion, cr denotes a contrast of a moving object, freq denotes a spatial frequency of the moving object, and a, b, c, d and e represent a weighting factor.

In the case in which the motion information is a still picture, the calculation of the Equation 3 is not carried out but the black display time ratio is set to be the lowest black display time ratio which is set. For example, when a predetermined black display time ratio is 0% to 50%, the black display time ratio is 0% if the motion information is the still picture.

Next, each weighting factor is set to be a=3, b=−0.4, c=0.06, d=0.001 and e=0.4 based on the result of a subjective evaluation experiment in the embodiment.

The black display time ratio obtained by the Equation 3 is output as the black display time ratio to the backlight luminance controller 20. Moreover, an image signal and a control signal corresponding to the black display time ratio are output to the liquid crystal panel 18.

In the case in which the black display time ratio obtained by the Equation 3 is not within a predetermined black display time ratio control range, it is rounded into a predetermined black display time ratio range. For example, in the case in which the black display time ratio range is set to be 0% to 50%, it is rounded to 50% if the black display time ratio is calculated to be 60% in the Equation 3.

(3-2) Relationship between Speed of Moving object and Black Display Time Ratio

Furthermore, a specific example will be described.

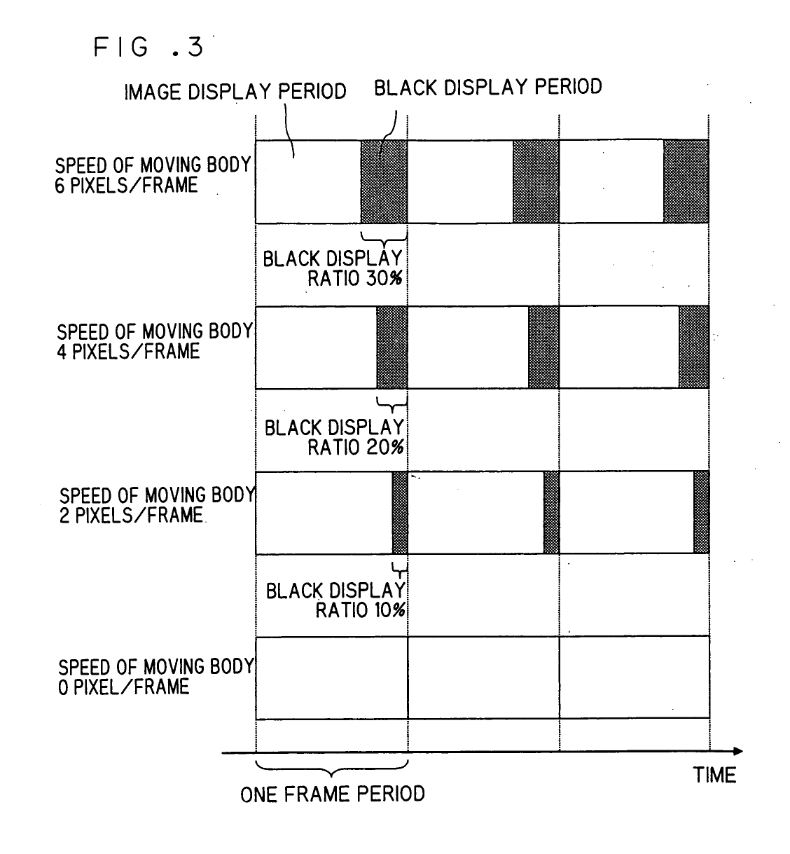

FIG. 3 typical shows a relationship between a speed of a moving object and a black display time ratio in a motion picture in which the moving object is moved over a still picture background. For simplicity of explanation, only the speed of the moving object is different. More specifically, in the Equation 3, it is assumed that dir, cr and freq are identical and only spd is changed. A black display time ratio control range is set to be 0% to 50%.

In case of the motion picture, the black display time ratio is changed depending on the speed of the moving object. For example, in FIG. 3, the black display time ratio is 30% when the speed of the moving object is 6 pixels/frame (a movement is carried out by 6 pixels per frame), while the black display time ratio is 20% when the speed of the moving object is 4 pixels/frame. Similarly, the black display time ratio is 10% when the speed of the moving object is 2 pixels/frame, while the black display time ratio is 0% when the speed of the moving object is 0 pixel/frame, that is, an input image is a still picture. As described above, the black display time ratio is changed corresponding to the motion information of an input image.

Although the case in which the speed of the moving object is changed has been taken as an example, the black display time ratio is changed depending on a directivity of a motion and the black display time ratio is changed moment by moment depending on an input image.

(4) Liquid Crystal Panel 18

(4-1) Structure of Liquid Crystal Panel 18

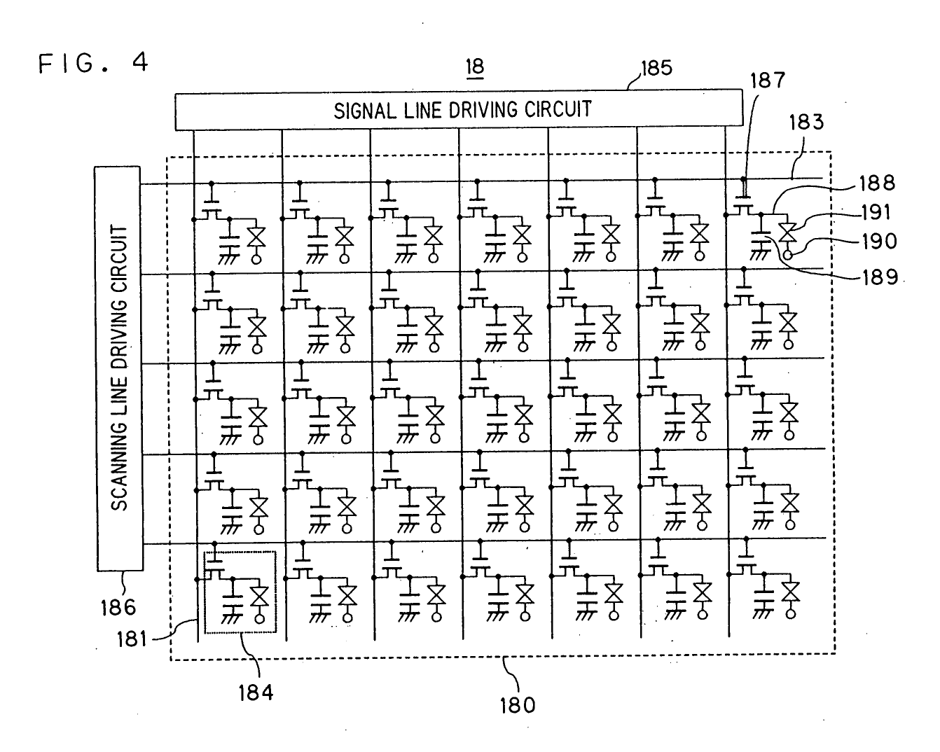

The liquid crystal panel 18 is of an active matrix type in the embodiment. As shown in FIG. 4, a plurality of signal lines 182 and a plurality of scanning lines 183 crossing them are disposed in a matrix over an array board 180 through an insulating film which is not shown, and a pixel 184 is formed in each of the crossing portions of both of the lines 182 and 183. Ends of the signal line 182 and the scanning line 183 are connected to a signal line driving circuit 185 and a scanning line driving circuit 186, respectively.

In the pixel 184, a switch unit 187 formed of a thin film transistor (TFT) is a switch unit configured to write an image signal and a gate thereof is connected to the scanning line 183 in common for each horizontal line. Moreover, a source is connected to the signal line 182 in common for each vertical line. Furthermore, a drain is connected to a pixel electrode 188 and an auxiliary capacity 189 provided electrically in parallel with the pixel electrode 188.

The pixel electrode 188 is formed on the array board 180 and a counter electrode 190 which is electrically relative to the pixel electrode 188 is formed on a counter board which is not shown. A predetermined counter voltage is applied from a counter voltage generating circuit (not shown) to the counter electrode 190. Moreover, a liquid crystal layer 191 is held between the pixel electrode 188 and the counter electrode 190, and the periphery of the array board 180 and the counter board are sealed with a sealant which is not shown.

Any liquid crystal material may be used for the liquid crystal layer 191. Since the liquid crystal panel 18 according to the embodiment is to write two image signals for an image display and a black display for one frame period as will be described below, it desirably responds at a comparatively high speed. For example, a ferroelectric liquid crystal or a liquid crystal in an OCB (Optically Compensated Bend) mode is preferable.

The scanning line driving circuit 186 is constituted by a shift register, a level shifter and a buffer circuit which are not shown. The scanning line driving circuit 186 outputs a row selection signal to each scanning line 183 based on a vertical start signal and a vertical clock signal which are output as control signals from the display ratio controller 16.

The signal line driving circuit 185 is constituted by an analog switch, a shift register, a sample hold circuit and a video bus which are not shown. A horizontal start signal and a horizontal clock signal output as control signals from the display ratio controller 16 are input to the signal line driving circuit 185 and an image signal is input thereto.

(4-2) Function of Liquid Crystal Panel 18

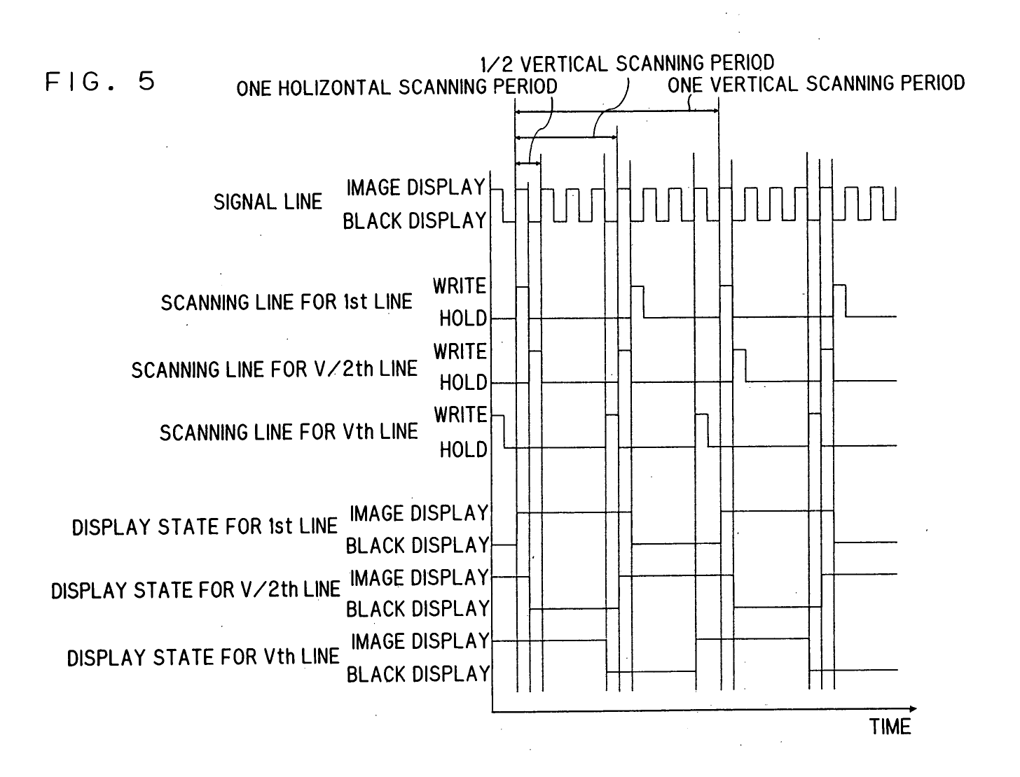

Next, description will be given to an operation of the liquid crystal panel 18 according to the embodiment. FIG. 5 is a timing chart for the liquid crystal panel 18 according to the embodiment. FIG. 5 shows driving waveforms of a display signal output from the signal line driving circuit 185 and a scanning line signal output from the scanning line driving circuit 186 and an image display state in the liquid crystal panel 18. For simplicity of the description, a blanking period is not shown in FIG. 5, and a general driving signal of the liquid crystal panel 18 usually has horizontal and vertical blanking periods.

An image display signal and a black display signal are output from the signal line driving circuit 185 in first and second halves of one horizontal scanning period, respectively. In the scanning line driving circuit 186, the scanning line 183 corresponding to each pixel 184 to supply the image display signal is selected in the first half of one horizontal scanning period and the scanning line 183 corresponding to each pixel 184 to supply the black display signal is selected in the second half of the horizontal scanning period.

FIG. 5 is a timing chart in the case in which a black display time ratio is 50%.

When the scanning line 183 for a first line is selected and the image display signal is supplied to the pixel 184 corresponding thereto in the first half of the horizontal scanning period, the scanning line 183 for a (V/2+1) th line is selected and the black display signal is supplied to the pixel 184 corresponding thereto in the second half of the horizontal scanning period, wherein the number of vertical scanning lines is represented as V.

When the scanning line 183 for a second line is selected in the first half of the horizontal scanning period, similarly, the scanning line 183 for a (V/2+2)th line is selected in the second half of the horizontal scanning period.

In the same manner, subsequent scanning lines 183 are sequentially selected in the first and second halves of the horizontal scanning period, respectively.

When the scanning line 183 for a Vth line is selected and the image display signal is supplied to the pixel 184 corresponding thereto in the first half of the horizontal scanning period, thus, the scanning line 183 for a (V/2) th line is selected and the black display signal is supplied to the pixel 184 corresponding thereto in the later half of the horizontal scanning period.

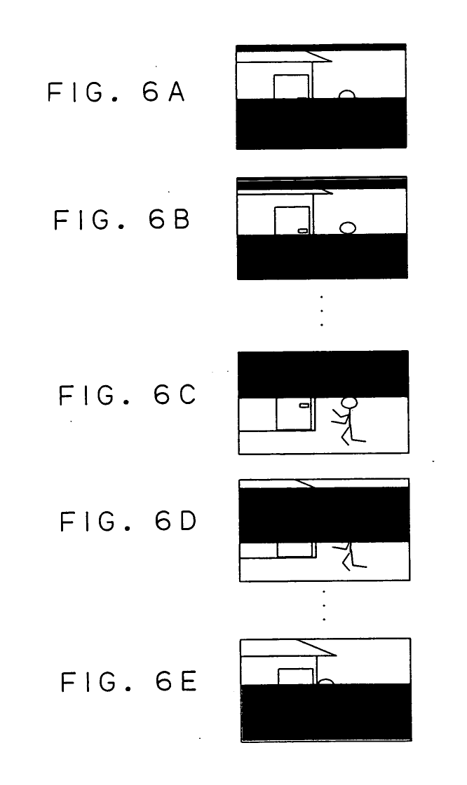

FIG. 6 shows a display state on the liquid crystal panel 18 in the case in which the black display time ratio is 50%. FIG. 6(a) shows a display state in which an image display signal for an nth frame is completely written to the (V/2+1)th line and the black display signal is written to the first line. FIG. 6(b) shows a display state in which an image display signal for an nth frame is written to the (V/2+2)th line and the black display signal is written to the second line. FIG. 6(c) shows a display state in which an image display signal for an nth frame is written to the Vth line and the black display signal is written to the (V/2−1)th line. FIG. 6(d) shows a display state in which an image display signal for an (n+1)th frame is written to the first line and the black display signal is written to the Vth line. FIG. 6(e) shows a display state in which an image display signal for an (n+1)th frame is written to the V/2th line and the black display signal is written to the Vth line.

While FIG. 5 shows the case in which the black display time ratio is 50%, similarly, it is possible to set an optional black display period by changing a write start timing for the black display signal, that is, changing a timing for the scanning line signal. By determining the black display time ratio in the display ratio controller 16 and inputting the write start timing for the black display signal as a control signal to the liquid crystal panel 18, consequently, it is possible to display an image on the liquid crystal panel 18 based on an optional black display time ratio.

(5) Backlight Luminance Controller 20

(5-1) Structure of Backlight Luminance Controller 20

In the backlight luminance controller 20, a backlight luminance control signal for controlling a light source of the backlight 22 is output by using information about a black display time ratio which is input.

More specifically, an analog voltage signal is output if the light source of the backlight 22 is an analog modulating LED, and a pulse width modulating signal is output if the same light source is a pulse width modulating (PWM) LED.

If the light source is a cold cathode tube, moreover, an analog voltage input to an inverter for turning on the cold cathode tube is output.

In the embodiment, an LED light source using a pulse width modulating method which can take a large dynamic range of a luminance is used with a comparative simple structure. A relationship between a pulse width to be input to the LED light source and the luminance of the backlight 22 is previously measured and is held in the backlight luminance controller 20. For data to be held, it is preferable to hold a function in the case in which the relationship can be expressed in the function, for example.

Moreover, the data may be held as LUT (Look-up Table) in an ROM.

If the LED light source has such a structure as to mix LEDs having three primary colors of red, green and blue and to display a white color, furthermore, it is desirable to hold data of the respective LEDs.

(5-2) Relationship between Black Display Time Ratio and Relative Luminance

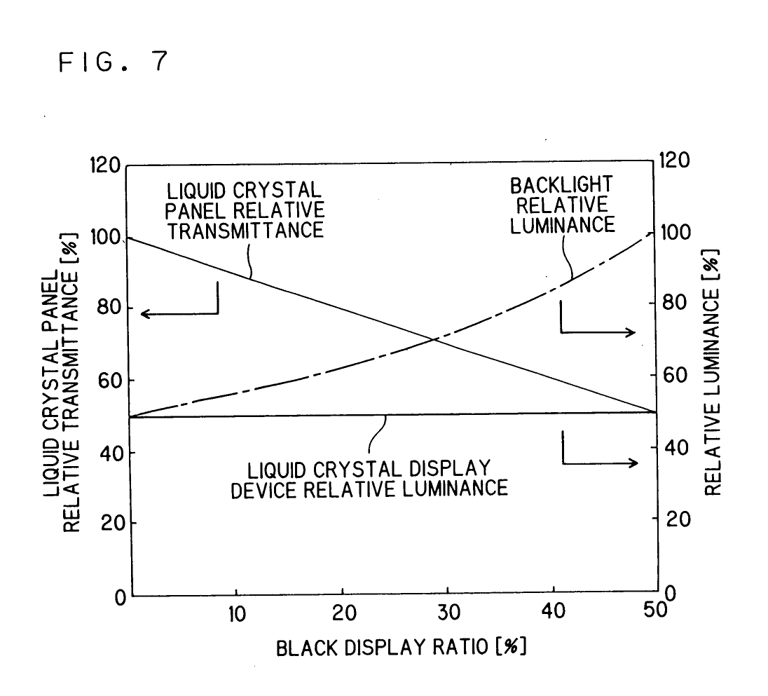

FIG. 7 shows a relationship between a black display time ratio and a liquid crystal panel relative transmittance, a backlight relative luminance and a relative luminance of a liquid crystal display device in the case in which a black display time ratio range is set to be 0% to 50%. An axis of abscissa indicates a black display time ratio, an axis of ordinate on a left side indicates a relative transmittance to a transmittance of the liquid crystal panel 18 when the black display time ratio is 0%, and an axis of ordinate on a right side indicates a relative luminance to a luminance of the backlight 22 when the black display time ratio is 100%.

In the liquid crystal panel 18 used in the embodiment, when the black display time ratio is increased, the transmittance is decreased linearly. For this reason, the luminance of the backlight 22 is increased when the black display time ratio is increased, and the luminance of the backlight 22 is controlled in such a manner that the relative luminance of the liquid crystal display device 10, that is, a luminance obtained after a transmission through the liquid crystal panel 18 is constant. In FIG. 7, a relationship between the black display time ratio and the relative luminance of the backlight 22 can be obtained. Furthermore, it is possible to obtain a relationship between the black display time ratio and a pulse width from the relationship between the backlight relative luminance and a pulse width to be input to the LED light source, and to obtain a backlight luminance control signal expressed in a pulse width based on the information about the black display time ratio which is acquired in the display ratio controller 16.

While the control is carried but in such a manner that the luminance is always constant for one frame period over the liquid crystal panel 18 displayed at various black display time ratios, it is also possible to perform such a control as to suppress a fluctuation in the luminance within a predetermined range around a luminance to be a reference for the frame period. More specifically, if such a control as to suppress the fluctuation in the luminance is carried out within a range in which a change in the luminance is not felt by human eyes, the object of the embodiment can be achieved.

(5-3) Variant of Backlight Luminance Controller 20

While the description has been given to the method of holding the relationship between the pulse width and the backlight luminance as data, it is also possible to hold the relationship between the black display time ratio and the pulse width which gives a constant luminance over the liquid crystal panel 18 displayed in various black display time ratios.

More specifically, a white image is displayed on the liquid crystal panel 18 at a certain black display time ratio and the luminance of the backlight 22 is controlled in such a manner that the luminance obtained after the transmission through the liquid crystal panel 18 has a predetermined value, and a pulse width input to the LED light source at that time is obtained. The operation is carried out at various black display time ratios, thereby obtaining the relationship between the black display time ratio and the pulse width and holding the relationship as data. By referring to the data based on the information about the black display time ratio which is input, the luminance of the backlight 22 can be controlled. Consequently, it is possible to hold the luminance on the liquid crystal panel 18 to be constant with respect to an optional black display time ratio.

In addition, it is also possible to employ a method of disposing a photodiode in the backlight 22 and carrying out a feedback while measuring the luminance of the backlight 22 by means of the photodiode, thereby controlling the luminance of the LED light source. In particular, the light emitting characteristic of the LED light source is changed depending on a temperature. Therefore, the structure for carrying out the feedback through the photodiode as described above is effective.

(6) Backlight 22

While the backlight 22 can be constituted by various light sources as described above, a vertical type backlight 22 using an LED as a light source is employed in the embodiment. The structure of the backlight 22 is not restricted to the above structure but an edge light type backlight 22 using a light guide plate may be employed, for example. A luminance of the backlight 22 is controlled in response to a backlight luminance control signal output from the backlight luminance controller 20.

(7) Advantage of Liquid Crystal Display Device 10

Next, description will be given to the advantage of the liquid crystal display device 10 according to the embodiment.

The liquid crystal display device 10 according to the invention determines the black display time ratio of the liquid crystal display device from motion information about an input image. This is intended for displaying an input image on the liquid crystal display device 10 at a black display time ratio which is as low as possible without deteriorating the picture quality of a motion picture due to the input image, thereby suppressing an increase in a consumed power and enhancing the picture quality of the motion picture.

For example, as shown in The Institute of Electronics, Information and Communication Engineers, Technical Report EID99-10 (1996-06), pp. 55 to 60, the picture quality of a motion picture based on a black display time ratio has a characteristic varied depending on the moving speed of the motion picture. To the contrary, it is indicated that the black display time ratio required for achieving constant picture quality of the motion picture is varied depending on the moving speed of the motion picture. In the liquid crystal display device 10 according to the embodiment, therefore, four parameters are obtained as the motion information from the input image as described above and the black display time ratio required for achieving the constant picture quality of the motion picture is calculated by the four parameters. Consequently, it is possible to suppress an increase in the luminance of the backlight 22 due to an excessive increase in the black display time ratio.

As described above, according to the liquid crystal display device 10 in accordance with the embodiment, it is possible to enhance the picture quality of a motion picture displayed on the liquid crystal display device 10 while suppressing an increase in a consumed power.

### Second Embodiment

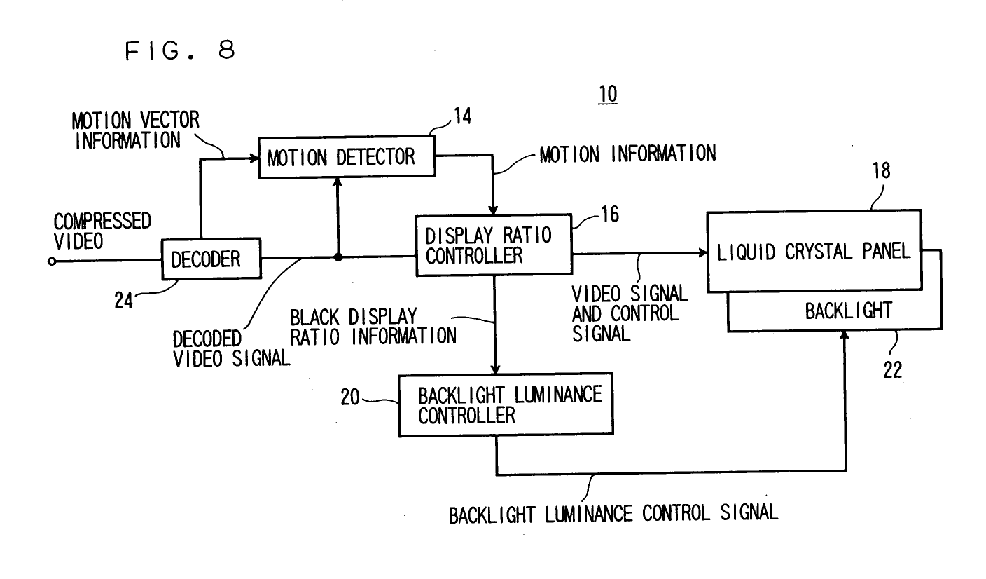

A liquid crystal display device 10 according to a second embodiment of the invention will be described with reference to FIG. 8.

FIG. 8 shows a structure of the liquid crystal display device 10 according to the embodiment.

The liquid crystal display device 10 according to the second embodiment has a basic structure which is the same as that in the first embodiment, and an input image is a compressed image including motion vector information and the liquid crystal display device 10 includes a decoder 24 for the compressed image and has such a structure as to output the motion vector information obtained in a decoding process to a motion detector 14.

The compressed input image including the motion vector information is input to the decoder 24. The compressed image including the motion vector information is MPEG2, for example. An image used in a broadcast at present is changed into an image compressed by the MPEG2, and furthermore, most of images stored in a personal computer are compressed images including the motion vector information. Therefore, the structure can be applied to various liquid crystal display devices 10. The decoder 24 decodes the compressed image and generates an image for an frame. Moreover, the motion vector information obtained in the decoding process is output to the motion detector 14.

Although the motion detector 14 detects the motion vector by block matching in the first embodiment, the motion vector information obtained in the decoding process of the decoder 24 is exactly used to generate the motion information in the embodiment. More specifically, the detection of the motion vector in the first embodiment is omitted and the motion vector obtained in the process for decoding the compressed image is used. With the structure, the detection of the motion vector can be omitted. Therefore, it is possible to reduce the amount of a processing of the motion detector 14. The following structure is the same as that in the first embodiment.

As described above, according to the liquid crystal display device 10 in accordance with the embodiment, it is possible to enhance the picture quality of a motion picture displayed on the liquid crystal display device 10 while suppressing an increase in a consumed power.

### Third Embodiment

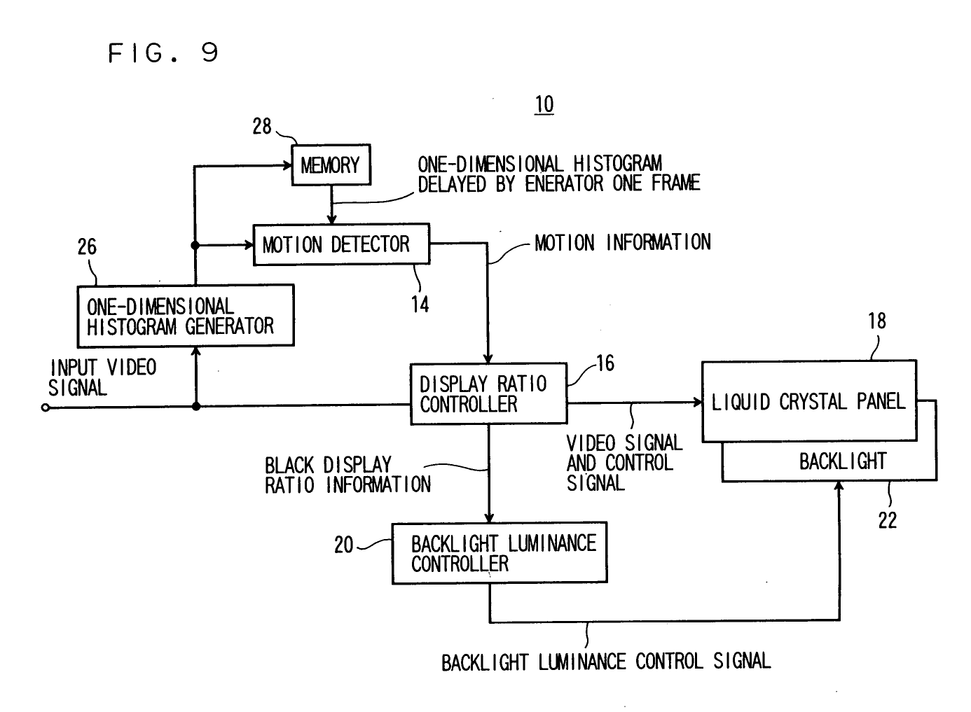

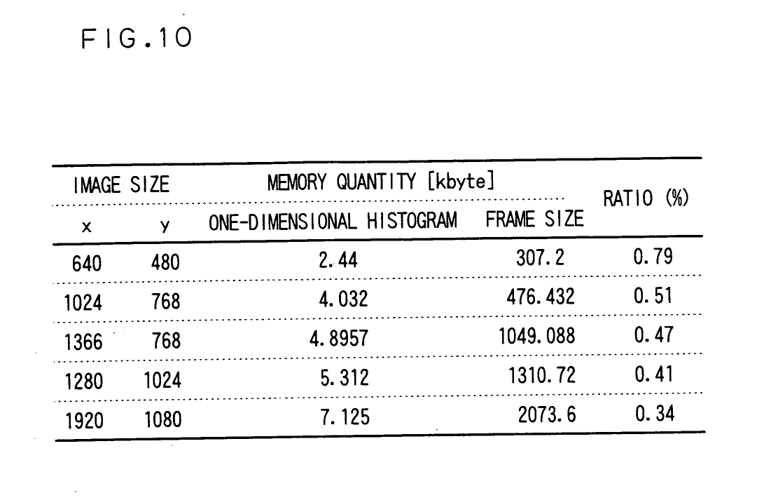

A liquid crystal display device 10 according to a third embodiment of the invention will be described with reference to FIGS. 9 and 10.

(1) Structure of Liquid Crystal Display Device 10

FIG. 9 shows a structure of the liquid crystal display device 10 according to the third embodiment of the invention.

The liquid crystal display device 10 according to the third embodiment has a basic structure which is the same as that in the second embodiment and in which a one-dimensional image obtained by adding an input image in horizontal and vertical directions is used to detect a motion of the input image.

The input image is input to a one-dimensional image generator 26 and is converted from two-dimensional image data into one-dimensional image data. The one-dimensional image is input to a motion detector 14 together with a one-dimensional image delayed by one frame period through a memory 28 and motion information is generated in the same manner as in the first embodiment. By the same processing as that in the first embodiment, the input image is displayed on the liquid crystal display device 10.

(2) One-dimensional Image Generator 26

Next, description will be given to an operation of the one-dimensional image generator 26.

In the one-dimensional image generator 26, image data for one frame are added in vertical and horizontal directions to generate a one-dimensional image. When a vertical projection image obtained by adding, in a vertical direction, pixels in a horizontal pixel position i in an image having a horizontal pixel number X and a vertical pixel number Y in an Nth frame is represented as Hv(i, N) and a horizontal projection image obtained by adding, in a horizontal direction, pixels in a vertical pixel position i is represented as Hh(i, N), the vertical projection image and the horizontal projection image can be calculated by Equations 4 and 5.
[Equation 4]

$${H}_{k} ( i , N ) = {\sum }_{x = 1}^{x} f ( x , i , N ) ( 1 ≦ i ≦ Y ) \qquad [ Equation 5 ]$$

wherein f(x, y, N) represents a function to calculate a Y value (a luminance value) from pixel values for red, green and blue in a position (x, y) in the Nth frame.
f(x,y,N)=0.299R(x,y,N)+0.587G(x,y,N)+0.114B(x,y,N) [Equation 6]

While the Y value is calculated from an image constituted by subpixels of red, green and blue in the embodiment, it is also possible to employ a structure in which the subpixels values for red, green and blue are exactly used to obtain a one-dimensional image.

In the case in which the one-dimensional image is used, it is possible to more reduce a necessary memory capacity as compared with the case in which a whole frame is used. FIG. 10 shows a necessary memory capacity based on an image size. A frame size in FIG. 10 is a memory capacity required for holding the whole frame. It is assumed that the Y value of each pixel

$${H}_{v} ( i , N ) = {\sum }_{y = 1}^{y} f ( i , y , N ) ( 1 ≦ i ≦ X )$$

is quantized in 8 bits. From FIG. 10, it is apparent that the memory capacity can be reduced to be 1% or less by using the one-dimensional image as compared with the case in which the frame memory 12 is used.

While the one-dimensional images in the vertical and horizontal directions are used in the embodiment, it is also possible to employ a structure in which only a one-dimensional image in the vertical direction is used, for example. The reason is as follows. In particular, an image to be broadcast in a television has more motion pictures including a motion in a transverse direction as compared with a motion in a longitudinal direction, and a motion of a whole input image can be detected schematically even if only a motion in a lateral direction, that is, a horizontal direction is detected.

While one horizontal projection image and one vertical projection image are obtained from a whole frame in the embodiment, moreover, it is also possible to employ a structure in which one frame is divided into a plurality of regions and a one-dimensional image for each region is obtained. For example, there is employed a structure in which one frame is divided into four portions to obtain one-dimensional vertical and horizontal projection images for each region. With the structure, also in the case in which an image size for one frame is large as in HDTV (High Definition Television), the frame is divided into a plurality of regions. Therefore, it is possible to obtain motion information from the one-dimensional image with high precision. Moreover, it is also possible to employ a method of adding a difference between a noted pixel and a peripheral pixel as well as a method of obtaining the one-dimensional image by an addition as described above. For example, it is also possible to employ a method of adding a difference value between the noted pixel and a pixel shifted by one pixel in a vertical direction (or an absolute value of the difference value).

(3) Motion Detector 14

(3-1) Function of Motion Detector 14

Next, description will be given to an operation of the motion detector 14.

In the embodiment, a motion vector is detected by block matching from one-dimensional images for an Nth frame and an (N+1)th frame. An evaluation criterion is set to be SAD and is obtained by Equation 7.

$$SAD ( d ) = {\sum }_{l ∈ B} \vert H ( i , N ) - H ( i + d , N + 1 ) \vert \qquad [ Equation 7 ]$$

wherein B indicates a region (line) to be a reference of a motion search and d indicates a candidate for a motion vector. SAD is obtained for various d and d having the smallest SAD is set to be a motion vector. This is expressed in Equation 8.

$$MV = arg {min}_{d ∈ W} ( SAD ( d ) ) \qquad [ Equation 8 ]$$

wherein W indicates a range in which d is estimated, that is, a search range and MV indicates a motion vector which is estimated.
(3-2) How to Obtain Motion Information

Next, how to obtain motion information will be described.

The motion information includes a speed of a motion, a directivity of the motion, a contrast of a moving object and a spatial frequency of the moving object in the same manner as in the first embodiment. How to obtain each motion information will be described below.

In a one-dimensional image, two-dimensional image data are projected onto a one-dimensional space. Therefore, information in a spatial direction is excluded. When the motion information about the spatial frequency of the moving object and the contrast of the moving object which will be described below are to be obtained, therefore, each motion information is calculated on the assumption that a phenomenon to generate each motion information in a 50% of a region for each of a height and a width of an image appears. For example, even if a difference in an absolute value of a vertical projection image is obtained to be 100 in the contrast of the moving object, it is impossible to know whether there are five differences of 20 or there is one difference of 100. In the case in which a height of an image has 10 pixels, therefore, the contrast of the moving object is obtained on the assumption that a difference is generated in 50% of the height of the image, that is, five pixels.

(3-2-1) Speed of Motion

1) Estimate a one-dimensional motion vector from each of a vertical projection image and a horizontal projection image, and obtain a motion vector having a scalar quantity of 1 or more.

2) Set the one-dimensional motion vector obtained from the vertical projection image to be a motion vector in an x direction and set the one-dimensional motion vector obtained from the horizontal projection image to be a motion vector in a y direction, thereby expanding them into a whole image. For example, in a region placed on an upper left part of an image, set a motion vector in a region on a left end of the vertical projection image and a motion vector of a block on an upper end of the horizontal projection image to be x and y components respectively, thereby obtaining a two-dimensional motion vector.

3) Classify the motion vector expanded into the whole image in the 2) into motion ranges in eight directions every 45 degrees (an upward direction of the image is set to be 0 degree, 45×N±22.5 degrees (N=0, 1, 2, 3, 4, 5, 6, 7)), and obtain the number of motion vectors corresponding to each motion range for each motion range.

4) Arrange the number of the motion vectors for each motion range obtained in the 3) in descending order and calculate a rate of the number of the motion vectors corresponding to each motion vector range to the number of the motion vectors having a scalar quantity of 1 or more which is obtained in the 1), and obtain a motion vector range of 90% or more in total. In the case in which the number of the motion vectors having a scalar quantity of 1 or more is smaller than 10% for a whole image, a speed of a motion is set to be 0 on the assumption that there is no motion.

5) Exclude, from the motion range obtained in the 4), a motion range in which the rate of the number of the motion vectors corresponding to each motion range to the number of the motion vectors having a scalar quantity of 1 or more is lower than 5%.

6) Obtain a scalar average of the motion vector corresponding to each motion range for each motion vector range obtained in the 5), and then weight average the scalar average of each motion vector at a rate of the number of the motion vectors corresponding to each motion range to the sum of the numbers of the motion vectors corresponding to a whole motion vector range obtained in the 5), and acquire a speed of a motion.

(3-2-2) Directivity of Motion

Set, as a directivity of a motion, the number of the motion vector ranges obtained in the 5) in which the speed of the motion is obtained.

(3-2-3) Contrast of Moving Object

1) Calculate a difference in an absolute value between the vertical projection images and the horizontal projection images in the Nth frame and the (N+1)th frame.

2) For each element of the difference in an absolute value which is obtained, divide an element value by 50% of a height of an image in case of the vertical projection image and divide an element value by 50% of a width of an image in case of the horizontal projection image. Calculate the number of elements having a value of 10 or more and a sum of the differences in an absolute value for each of the vertical projection image and the horizontal projection image.

3) Divide the sums of the differences in an absolute value of the vertical projection image and the horizontal projection image obtained in the 2) by the number of the elements, and furthermore, divide values thus obtained by 50% of the height of the image for the vertical projection image and 50% of the width of the image for the horizontal projection image respectively, and set a value obtained by adding them to be a contrast of a moving object.

(3-2-4) Spatial Frequency of Moving Object

1) Calculate an absolute difference value from an adjacent pixel (element positions of i and i+1) for a block having a scalar quantity of 1 or more of a motion vector for each of the vertical projection image and the horizontal projection image, and then divide the difference by 50% of the height of the image for the vertical projection image and 50% of the width of the image for the horizontal projection image.

2) Obtain the number of the elements for each of the vertical projection image and the horizontal projection image which has a value of 10 or more obtained in the 1).

3) Set, as a spatial frequency of the moving object, a value obtained by adding a value acquired by multiplying the number of the elements of the vertical projection image obtained in the 2) by 50% of the height of the image and a value acquired by multiplying the number of the elements in the horizontal projection image obtained in the 2) by 50% of the width of the image.

A subsequent structure according to the third embodiment is the same as that in the first embodiment, and a black display time ratio is calculated in a display ratio controller 16 based on the motion information obtained in the motion detector 14 and an input image is displayed on the liquid crystal display device. 10 at the black display time ratio which is calculated.

As described above, according to the liquid crystal display device 10 in accordance with the embodiment, it is possible to enhance picture quality of a motion picture displayed on the liquid crystal display device 10 while suppressing an increase in a consumed power. According to the embodiment, furthermore, it is possible to reduce a memory capacity and a processing cost which are required for obtaining the motion information.

### Fourth Embodiment

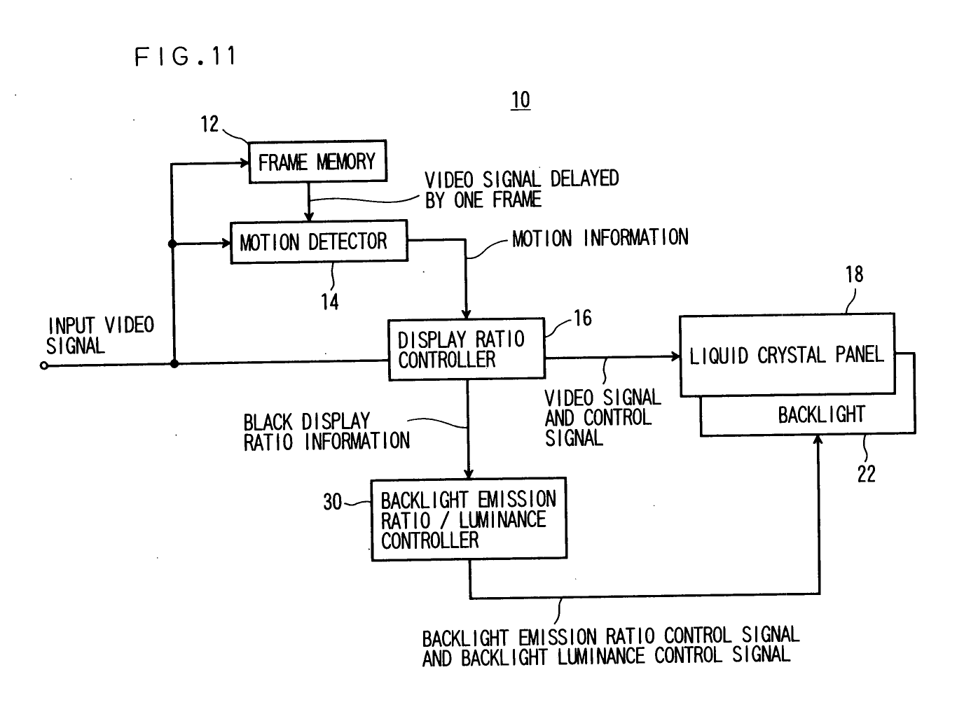

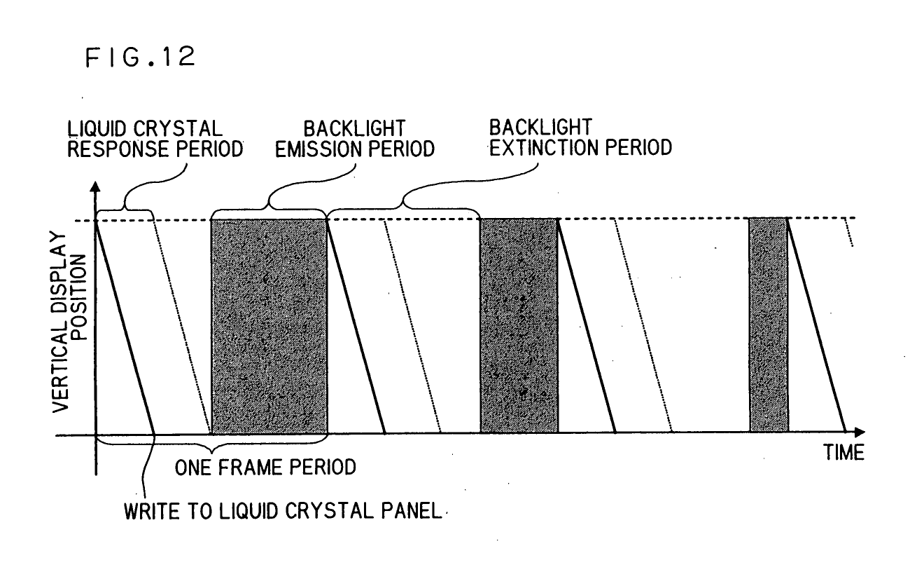

A liquid crystal display device 10 according to a fourth embodiment of the invention will be described with reference to FIGS. 11 and 12.

(1) Structure of Liquid Crystal Display Device 10

FIG. 11 shows a structure of the liquid crystal display device 10 according to the fourth embodiment of the invention.

The liquid crystal display device 10 according to the fourth embodiment has a basic structure which is the same as that in the first embodiment, and is characterized in that the light emission and extinction of a backlight 22 is controlled to control a display ratio of an input image displayed on the liquid crystal display device 10.

By the same structure as that in the first embodiment, a black display time ratio is determined from an input image. The black display time ratio thus determined is input as black display time ratio information to a backlight emission ratio/luminance controller 30. In the backlight emission ratio/luminance controller 30, a period for the light emission of the backlight 22 and a luminance of the light emission of the backlight 22 are determined based on information about a black display time ratio and are input as a backlight emission ratio control signal and a backlight luminance control signal to the backlight 22. The backlight 22 emits a light based on the backlight emission ratio control signal and the backlight luminance control signal which are input.

(2) Operation of Liquid Crystal Panel 18 and Backlight 22

Next, description will be given to operations of the liquid crystal panel 18 and the backlight 22.

FIG. 12 shows the operations of the liquid crystal panel 18 and the backlight 22. In FIG. 12, an axis of abscissa indicates a time and an axis of ordinate indicates a vertical display position of the liquid crystal panel 18.

In the liquid crystal panel 18, usually, an image is written linearly and sequentially from an upper part toward a screen. Accordingly, the image is written to the liquid crystal panel 18 while slightly shifting a writing time from the upper part toward the screen as shown in FIG. 12. In order to maintain a light emission period of the backlight 22 which will be described below, the write to the liquid crystal panel 18 is usually carried out for one frame period (generally 1/60 second). In the embodiment, the write is carried out for a shorter period than one frame period, that is, a ¼ frame period ( 1/240 second).

After a predetermined period passes till the completion of a response of a liquid crystal since the write of the lowermost line of the liquid crystal panel 18, the backlight 22 emits a light in response to the backlight emission ratio control signal.

A light emission luminance of the backlight 22 is determined by the backlight emission period and a control is carried out in such a manner that a product of the backlight emission period and the backlight emission luminance is approximately constant.

Moreover, it is desirable that the backlight 22 should extinguish a light for a period of the write to the liquid crystal panel 18 and a period of the response of the liquid crystal. The reason is as follows. For the period of the write to the liquid crystal panel 18 and the period of the response of the liquid crystal, an image in a part of a last frame is displayed on the liquid crystal panel 18. When the backlight 22 emits a light for the same period, therefore, the last frame and a current frame are mixed and presented to an observer.

By controlling the light emission period of the backlight 22 as described above, it is possible to control an image display period and a black image display period of the liquid crystal display device 10 in the same manner as in the first embodiment.

As described above, according to the liquid crystal display device 10 in accordance with the embodiment, it is possible to enhance the picture quality of a motion picture and a still picture which are displayed on the liquid crystal display device 10.

### Fifth Embodiment

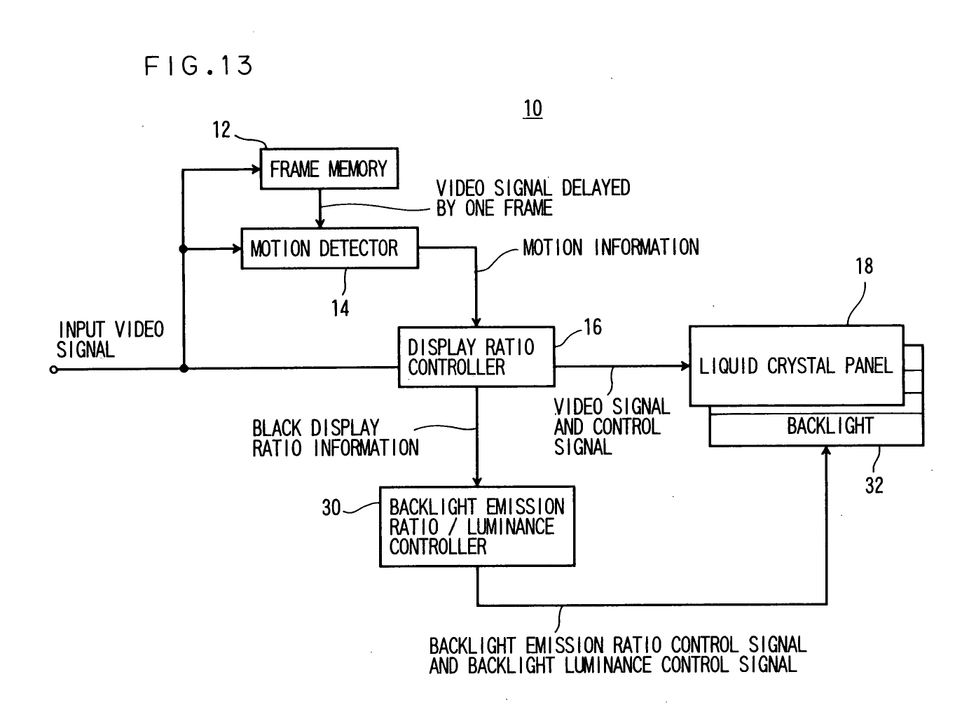

A liquid crystal display device 10 according to a fifth embodiment of the invention will be described with reference to FIGS. 13 to 15.

FIG. 13 shows a structure of the liquid crystal display device 10 according to the embodiment.

While the liquid crystal display device 10 according to the fifth embodiment has a basic structure as that in the fourth embodiment, a light emitting region of a backlight 22 is divided and a backlight 32 can be caused to emit a light in different timings.

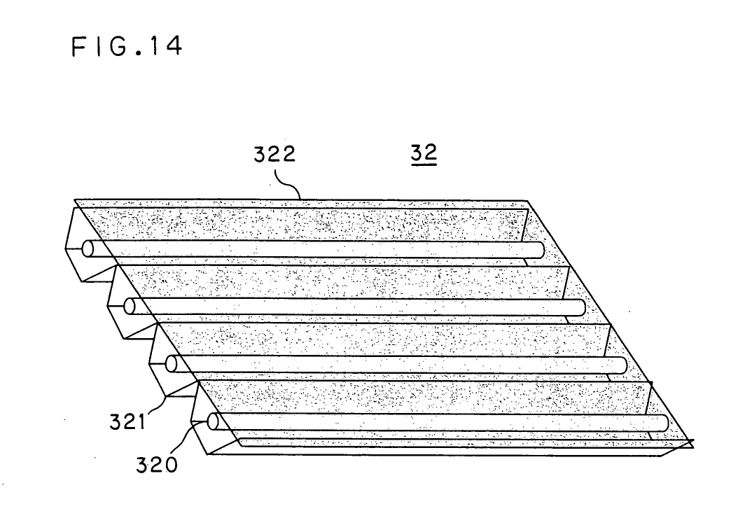

FIG. 14 shows an example of a structure of the backlight 32 according to the embodiment.

FIG. 14 shows a structure referred to as a vertical type backlight 32, and cold cathode tubes 320 are arranged as a light source and each of the cold cathode tubes 320 is surrounded by a reflecting plate 321. A diffusing plate 322 is disposed over the cold cathode tubes 320 and serves as a uniform surface light source to diffuse a light from the cold cathode tube 320. In the embodiment, a light emission timing of each cold cathode tube 320 is varied.

Next, description will be given to operations of a liquid crystal panel 18 and the backlight 32.

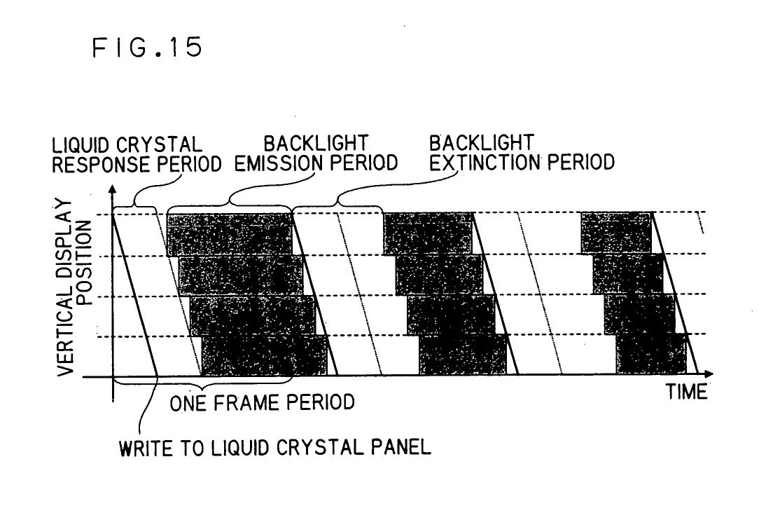

FIG. 15 shows the operations of the liquid crystal panel 18 and the backlight 32. In FIG. 15, the backlight 32 is divided into four portions in a vertical direction so that four horizontal light emitting regions are formed, and each of the horizontal light emitting regions can control the light emission and extinction timings of the backlight 32.

In the fourth embodiment, the light emission timing of the backlight 32 is set after a constant period since the write of the lowermost line of the liquid crystal panel 18.

In the embodiment, however, the backlight 32 emits a light in response to a light emission ratio control signal of the backlight 32 after a response period of a liquid crystal since the write of the lowermost line of the liquid crystal panel 18 corresponding to each of the regions obtained by the division.

In the case in which the light emitting region of the backlight 32 is divided as described above, it is possible to set the light emission period of the backlight 32 to be longer than that in the fourth embodiment. Consequently, it is possible to carry out a control at a display ratio within a larger range. Other structures are the same as those in the fourth embodiment.

As described above, according to the liquid crystal display device 10 in accordance with the embodiment, it is possible to enhance the picture quality of a motion picture and a still picture which are displayed on the liquid crystal display device 10.

### Sixth Embodiment

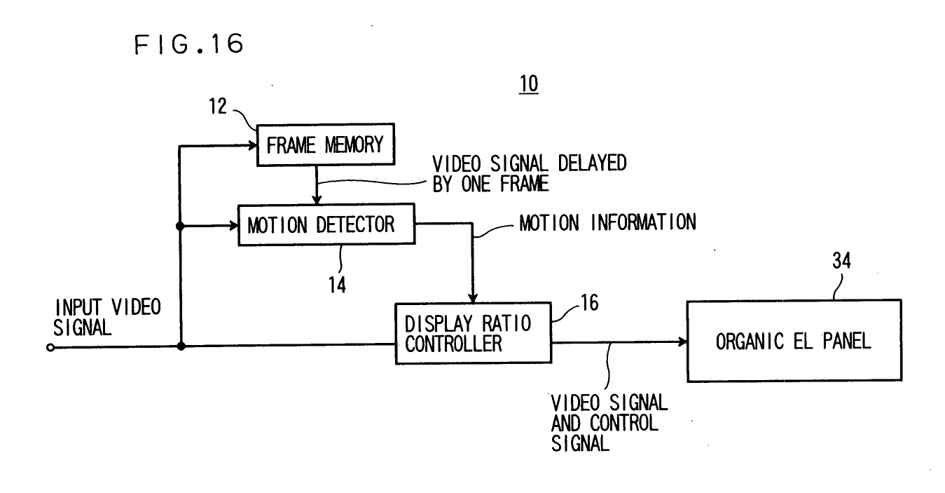

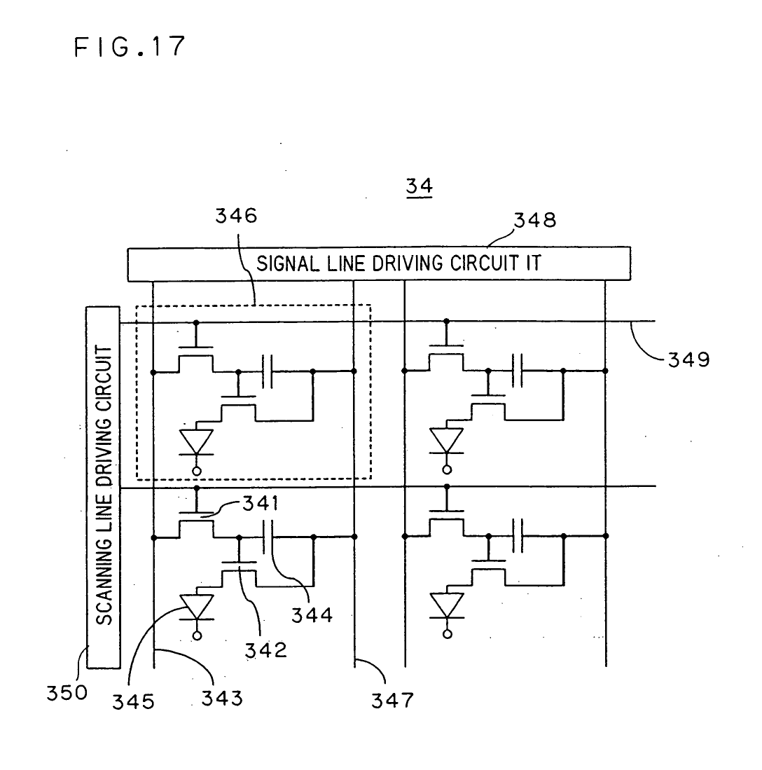

An organic EL display device 100 according to a sixth embodiment of the invention will be described with reference to FIGS. 16 and 17.

(1) Structure of Organic EL Display Device 100

FIG. 16 shows a structure of the organic EL display device 100 according to the sixth embodiment of the invention.

The organic EL display device 100 according to the sixth embodiment has a basic structure which is the same as that in the first embodiment, and an image display unit is constituted by an organic EL panel 34.

FIG. 17 shows an example of a structure of the organic EL panel 34.

In the organic EL panel 34, a pixel 346 is constituted by a first switch unit 341 and a second switch unit 342 which are formed by two thin film transistors, a voltage holding capacity 344 for holding a voltage supplied from a signal line 343, and an organic EL unit 345.

Ends of the signal line 343 and a power line 347 are connected to a signal line driving circuit 348.

A scanning line 349 in an orthogonal direction to the signal line 343 and the power line 347 is connected to a scanning line driving circuit 350.

(2) Operation of Organic EL Display Device 100

Next, description will be given to an operation of the organic EL display device 100.

A scanning line driving signal in an ON state is applied from a scanning line driving circuit 186 to the first switch unit 341 through a scanning line 183 so that the first switch unit 341 is brought into a conducting state. A signal line driving signal output from the signal line driving circuit 348 at that time is written to the voltage holding capacity 344 through the signal line 343.

The conducting state of the second switch unit 342 is determined depending on a quantity of electric charges stored in the voltage holding capacity 344 and a current is supplied to the organic EL unit 345 through the power line 347 so that the organic EL unit emits a light.

Even if the scanning line driving signal is brought into an OFF state, the current is continuously supplied to the organic EL unit 345 through the power line 347 because a voltage for determining the conducting state of the second switch unit 342 is stored in the voltage holding capacity 344.

In the same manner as in FIG. 5 showing the first embodiment, accordingly, an image signal and a black image signal are output from the signal line driving circuit 348 in first and second halves of one horizontal scanning period, and a scanning line driving signal which is synchronous and set in an ON state is applied to the scanning line 183 to write the image signal in the first half of the horizontal scanning period and the scanning line driving signal which is synchronous and set in the ON state is applied to the scanning line 183 to write the black image signal in the second half of the horizontal scanning period. In the same manner as in the first embodiment, consequently, it is possible to control the image display period and the black image display period of the organic EL panel 34. More specifically, the scanning line driving circuit 186 is controlled based on a black display time ratio determined by a display ratio control in the same manner as in the first embodiment.

(3) Peculiar Control to Organic EL Panel 34

The organic EL panel 34 is a spontaneous light emitting unit. For this reason, it is necessary to control a brightness of an image for a period in which an image is displayed depending on the black display time ratio, thereby controlling a luminance for one frame period so as to be almost constant.

In the embodiment, therefore, the brightness of an image is digitally controlled by using the signal line driving circuit 348 having precision in an output of 10 bits. In a state in which the black display time ratio is the highest within a predetermined control range, the brightness of the image is required most greatly. In other words, since the black display time ratio is high, a period for displaying an image is shortened. In order to cause the luminance for one frame period to be almost constant, consequently, it is necessary to increase the brightness of the image.

Within a predetermined black display time ratio control range, therefore, a maximum display gray-scale level of an image at a maximum black display time ratio is set to be 1020 gray-scale levels and is set to have a smaller value when the black display time ratio is more reduced. Consequently, a maximum luminance for an image display period is controlled. More specifically, when a gamma value of an input image is represented as γ, a maximum gray-scale level of the input image is set to be 8 bits (255 gray-scale levels) and a ratio of a luminance for an image display period at a black display time ratio to be set to a luminance for an image display period at a maximum black display time ratio within a black display time ratio control range is represented as I, a maximum gray-scale level Lmax set at the ratio I of a luminance is expressed in Equation 9.
Lmax=(I×(255×4)^{γ})^{1/γ} [Equation 9]

By the Equation 9, a maximum gray-scale level corresponding to the black display time ratio is obtained and all of the gray-scale levels of the image are then quantized again. Consequently, it is possible to control a brightness for the image display period.

By controlling a current value supplied through the power line 347, moreover, the organic EL panel 34 can control the brightness. Accordingly, it is also possible to employ a structure in which the current value supplied through the power line 347 is controlled in such a manner that the luminance for one frame period is caused to be almost constant depending on the black display time ratio.

Other structures are the same as those in the first embodiment.

As described above, it is possible to enhance the picture quality of a motion picture and a still picture which are displayed on the organic EL display device 100 according to the embodiment.

### Variant

While the embodiments according to the invention have been described above, the invention is not restricted to the embodiments but various changes can be made without departing from the scope of the invention.

Even if some of requirements which have been disclosed are deleted, for example, they can be extracted as the invention if predetermined advantages are obtained.

Although the liquid crystal display device 10 and the organic EL display device 100 have been described in the embodiment, moreover, a hold type display device to continuously display an image, thereby displaying a motion picture for one frame period can also enhance the picture quality of a motion picture and a still picture in accordance with the invention. For example, it is also possible to use an inorganic EL display device.

What is claimed is:

1. An image display device comprising:
a display to display an input image and a black image within one frame period;
a motion detector to detect a motion information from the input image;
a display ratio controller to set a black display time ratio as a ratio of a black period to said one frame period based on the motion information, the black period being a period for displaying the black image within said one frame period; and
a display luminance controller to suppress, within a predetermined range, a luminance fluctuation caused by a change in the black display time ratio, the luminance fluctuation corresponding to a fluctuation of a total luminance for said one frame period.

2. The image display device according to claim 1, wherein the display includes a liquid crystal panel and a surface light source unit to illuminate the liquid crystal panel from a back,
the display ratio controller controls the liquid crystal panel to display the input image and the black image based on the black display time ratio, and
the display luminance controller controls the surface light source unit to suppress, within a predetermined range, the luminance fluctuation.

3. The image display device according to claim 1, wherein the display includes a liquid crystal panel and a surface light source unit disposed on a back face of the liquid crystal panel, the surface light source unit illuminating the liquid crystal panel from the back of the liquid crystal panel,
the display ratio controller controls the liquid crystal panel to display the input image for said one frame period, and
the display luminance controller controls the surface light source unit to emit a light for a period in which the input image is to be displayed and to extinct for a period in which the black image is-to be displayed based on the black display time ratio.

4. The image display device according to claim 3, wherein the surface light source unit includes a plurality of horizontal light emitting regions which are divided in a vertical direction over a screen of the liquid crystal panel;
the surface light source unit controls light emission and extinction timings for each of the plurality of horizontal light emitting regions;
the input image data are written linearly and sequentially for each horizontal line from an end of the screen in the liquid crystal panel; and
the display luminance controller controls the surface light source unit as to extinguish one of the horizontal light emitting regions for a span of a black display time that depends on the black display time ratio, after the input image data are written to a region on the screen matching said one of the horizontal light emitting regions; and light up said one of horizontal light emitting regions during a time other than the black display time, after such extinguishing or in otherwise before such extinguishing and directly after the input image data being written.

5. The image display device according to claim 1, wherein the display is an electroluminescence panel.

6. The image display device according to claim 1, wherein the motion detector includes a memory which holds the input image,
the motion detector detects a motion vector by using a whole or part of a current input image and an input image delayed by a constant period through the memory and obtains a norm of the motion vector, and
the display ratio controller sets the black display time ratio based on the norm of the motion vector.

7. The image display device according to claim 1, wherein the motion detector includes a memory which holds the input image,
the motion detector detects a plurality of motion vectors by using a whole or part of a current input image and an input image delayed by a constant period through the memory and obtains a distribution of a direction of the plurality of motion vectors, and
the display ratio controller sets the black display time ratio based on the distribution of the direction of the plurality of motion vectors.

8. The image display device according to claim 1, wherein the motion detector includes a memory which holds the input image,
the motion detector obtains a difference between frames by using a whole or part of a current input image and an input image delayed by a constant period through the memory, and
the display ratio controller sets the black display time ratio based on the difference between the frames.

9. The image display device according to claim 1, wherein the motion detector obtains a spatial frequency of the input image, and
the display ratio controller sets the black display time ratio based on a distribution of the spatial frequency.

10. The image display device according to claim 6, wherein the motion vector is obtained by block matching of the current input image and the input image delayed by a constant period.

11. The image display device according to claim 6, wherein the motion detector projects the current input image onto a one-dimensional array image,
projects the input image delayed by a constant period onto the one-dimensional array image, and
detects a motion vector by using both of these one-dimensional array images.

12. The image display device according to claim 1, wherein the input image is encoded image data including motion vector,
the image display device further comprising a decoder which decodes the encoded image data and obtains a motion vector, and
the motion detector obtains motion information from the motion vector.

13. The image display device according to claim 6, wherein the display ratio controller obtains the black display time ratio by a weighting linear sum of a whole or part of the norm of the motion vector, a distribution of a direction of the motion vector, a difference between the frames and a distribution of the spatial frequency.

14. The image display device according to claim 1, wherein the display ratio controller sets the black display time ratio within a preset range.

15. The image display device according to claim 14, wherein the display ratio controller sets the black display time ratio in a plurality of discrete time ratios set within the range.

16. An image display device capable of displaying a motion picture, comprising:
a display to display an input image and a black image within one frame period of the motion picture, the input image corresponding to each frame of the motion picture;
a motion detector to detect a motion information from the input image, the motion information including a magnitude of the motion;
a display ratio controller to set a black display time ratio in such a manner that a black period for displaying the black image within said one frame period is more prolonged when the magnitude of the motion is more increased; and
a display luminance controller to suppress, within a predetermined range, a luminance fluctuation due to a change in the black display time ratio, the luminance fluctuation corresponding to a fluctuation of a total luminance for one frame period.

17. The image display device according to claim 16, wherein the display includes a liquid crystal panel and a surface light source unit to illuminate the liquid crystal panel from a back,
the display ratio controller controls the liquid crystal panel to display the input image and the black image based on the black display time ratio, and
the display luminance controller controls the surface light source unit to suppress, within a predetermined range, the luminance fluctuation.

18. The image display device according to claim 16, wherein the display includes a liquid crystal panel and a surface light source unit disposed on a back face of the liquid crystal panel, the surface light source unit illuminating the liquid crystal panel from the back of the liquid crystal panel,
the display ratio controller controls the liquid crystal panel to display the input image for said one frame period, and
the display luminance controller controls the surface light source unit to emit a light for a period in which the input image is to be displayed and to extinct for a period in which the black image is to be displayed based on the black display time ratio.

19. The image display device according to claim 16, wherein the motion detector includes a memory which holds the input image,
the motion detector detects a motion vector by using a whole or part of a current input image and an input image delayed by a constant period through the memory and obtains a norm of the motion vector, and
the display ratio controller sets the black display time ratio based on the norm of the motion vector.

20. The image display device according to claim 16, wherein the motion detector includes a memory which holds the input image,
the motion detector detects a plurality of motion vectors by using a whole or part of a current input image and an input image delayed by a constant period through the memory and obtains a distribution of a direction of the plurality of motion vectors, and
the display ratio controller sets the black display time ratio based on the distribution of the direction of the plurality of motion vectors.

21. The image display device according to claim 16, wherein the motion detector includes a memory which holds the input image,
the motion detector obtains a difference between frames by using a whole or part of a current input image and an input image delayed by a constant period through the memory, and
the display ratio controller sets the black display time ratio based on the difference between the frames.

22. The image display device according to claim 16, wherein the motion detector obtains a spatial frequency of the input image, and
the display ratio controller sets the black display time ratio based on a distribution of the spatial frequency.

23. The image display device according to claim 19, wherein the motion detector projects the current input image onto a one-dimensional array image,
projects the input image delayed by a constant period onto the one-dimensional array image, and
detects a motion vector by using both of these one-dimensional array images.

24. A method of displaying a motion picture on a screen of an image display device, comprising:
displaying an input image and a black image within one frame period of the motion picture, the input image corresponding to each frame of the motion picture;
detecting a motion information from the input image, the motion information including a magnitude of the motion;
setting a black display time ratio in such a manner that a black period for displaying the black image within said one frame period is more prolonged when the magnitude of the motion is more increased; and
suppressing, within a predetermined range, a luminance fluctuation due to a change in the black display time ratio, the luminance fluctuation corresponding to a fluctuation of a total luminance for one frame period.

25. A program product for displaying a motion picture, comprising instructions of:
displaying an input image and a black image within one frame period of the motion picture, the input image corresponding to each frame of the motion picture;
detecting a motion information from the input image, the motion information including a magnitude of the motion;
setting a black display time ratio in such a manner that a black period for displaying the black image within said one frame period is more prolonged when the magnitude of the motion is more increased; and
suppressing, within a predetermined range, a luminance fluctuation due to a change in the black display time ratio, the luminance fluctuation corresponding to a fluctuation of a total luminance for one frame period.
